(19) United States
(12) Patent Application Publication
(10) Pub. No.: US 2022/0254976 A1
(43) Pub. Date: Aug. 11, 2022

(54) BISMUTH TELLURIDE-BASED THERMOELECTRIC NANOCOMPOSITES WITH DISPERSED NANO-SIZED SILICON CARBIDE BASED ON THE RECYCLING OF BISMUTH TELLURIDE PROCESSING SCRAPS AND PREPARATION METHOD THEREOF

(71) Applicant: TSINGHUA UNIVERSITY, BEIJING (CN)

(72) Inventors: JINGFENG LI, BEIJING (CN); BOWEN CAI, BEIJING (CN)

(21) Appl. No.: 17/569,651

(22) Filed: Jan. 6, 2022

(30) Foreign Application Priority Data
Feb. 9, 2021 (CN) 202110178320.6

(51) Int. Cl. H01L 35/26; H01L 35/34

(52) U.S. Cl. CPC H01L 35/26; H01L 35/34

(57) ABSTRACT

Disclosed are a bismuth telluride-based thermoelectric nanocomposite with dispersed nano-sized silicon carbide based on the recycling of bismuth telluride processing scraps, wherein the method comprises: (1) Under a protective atmosphere, mixing bismuth telluride processing scraps and nano-sized silicon carbide, and then performing ball milling; (2) Subjecting the ball-milled powders to spark plasma sintering to obtain a bismuth telluride-based thermoelectric nanocomposite with dispersed nano-sized silicon carbide. The method can significantly improve the utilization rate of bismuth telluride processing scraps and avoid the waste of precious materials. Moreover, the process has the characteristics of simple and easy operation, and low energy consumption. The obtained bismuth telluride-based thermoelectric nanocomposite with dispersed nano-sized silicon carbide has high thermoelectric performance, which can be widely used in the fields of thermoelectric power generation and refrigeration.

### TECHNICAL FIELD

The present disclosure belongs to the technical field of energy materials, and specifically relates to a bismuth telluride-based thermoelectric nanocomposite with dispersed nano-sized silicon carbide based on the recycling of bismuth telluride processing scraps and a preparation method thereof.

### BACKGROUND ART

Thermoelectric materials can achieve the direct conversion between heat and electricity via the thermoelectric effect. Devices made of thermoelectric materials have many advantages such as no moving parts, environmental friendly, and high reliability. Therefore, they have attracted the attention of both academia and industry. The thermoelectric performance of a material is usually characterized by a dimensionless figure of merit ZT: ZT=S²σT/κ, S is the Seebeck coefficient, σ is the electrical conductivity, T is the absolute temperature, and κ is the thermal conductivity. It can be seen from this equation that excellent thermoelectric materials require high S and σ, while low κ. Thermoelectric materials can be divided into near room temperature, medium temperature, and high temperature materials according to the operating temperature range. Thermoelectric materials applied in near room temperature range are mainly used for solid-state refrigeration, which applied in medium and high temperature ranges are mostly used for power generation.

Bismuth telluride-based thermoelectric materials are a kind of classical near room temperature thermoelectric materials and also the only materials for large scale commercial application. At present, most of the industrial bismuth telluride-based thermoelectric materials are fabricated via the zone-melting method, and the ZT value is 0.9-1.0. Although the zone-melting method can realize mass production, it is time and energy consuming. In addition, bismuth telluride-based material has an intrinsic layered crystal structure, the ingot obtained by zone-melting is brittle and easy to cleavage between the layers, so a large amount of bismuth telluride processing scraps will be generated during the preparation process of thermoelectric devices. The material utilization rate is only 50%, which not only increases the difficulty of device preparation, but also causes the waste of precious raw materials. Therefore, recycling of bismuth telluride processing scraps and further improving the thermoelectric performance have increasingly become an issue that concerned by both of academia and industry, that is urgently need to be solved.

### SUMMARY

The present disclosure aims to solve one of the technical problems in the related fields at least to a certain extent. Therefore, an object of the present disclosure is to provide a bismuth telluride-based thermoelectric nanocomposite with dispersed nano-sized silicon carbide based on the recycling of processing scraps and a preparation method thereof, which can significantly improve the utilization rate of bismuth telluride processing scraps and avoid the waste of precious materials. In addition, the process has the characteristics of simple and easy operation, and low energy consumption. The obtained bismuth telluride-based thermoelectric nanocomposite with dispersed nano-sized silicon carbide has high thermoelectric performance, which can be widely used in the fields of thermoelectric power generation and refrigeration.

In one aspect of the present disclosure, the present disclosure provides a method for preparing a bismuth telluride-based thermoelectric nanocomposite with dispersed nano-sized silicon carbide based on the recycling of bismuth telluride scraps, wherein comprising:

(1) Under a protective atmosphere, mixing bismuth telluride processing scraps and nano-sized silicon carbide, and then performing ball milling;

(2) Subjecting the ball-milled powders to spark plasma sintering to obtain a bismuth telluride-based thermoelectric material with dispersed nano-sized silicon carbide.

According to the method for preparing the bismuth telluride-based thermoelectric material with dispersed nano-sized silicon carbide based on the recycling of bismuth telluride scraps in an embodiment of the present disclosure, the bismuth telluride processing scraps and nano-sized silicon carbide are mixed and subjected to ball milling in a protective atmosphere. Ball milling process does not involve high temperature, which avoids the elements volatilization. Besides, ultra-fine ball-milled powders can be obtained efficiently. The dispersion of nano-sized silicon carbide can not only improve the thermoelectric performance of bismuth telluride-based nanocomposite, but also increase the hardness, which is conducive to subsequent material processing. Then, the obtained ball-milled powders are subjected to spark plasma sintering, and a fine-grained bulk bismuth telluride-based thermoelectric nanocomposite with dispersed nano-sized silicon carbide can be obtained in a short time. Therefore, the method can significantly improve the utilization rate of bismuth telluride processing scraps, and avoid the waste of precious materials. The preparation process has the characteristics of simple and easy operation, and low energy consumption. At the same time, the obtained bismuth telluride-based thermoelectric nanocomposite with dispersed nano-sized silicon carbide has high thermoelectric performance and can be widely used in the fields of thermoelectric power generation and refrigeration.

In addition, the method for preparing the bismuth telluride-based thermoelectric nanocomposite with dispersed nano-sized silicon carbide based on the recycling of bismuth telluride processing scraps according to the above embodiment of the present disclosure may also have the following additional technical features:

In some embodiments, in step (1), the conditions of the ball milling are as follows: the weight ratio of balls to powders is (15-30):1, the ball milling speed is 400-500 r/min, and the ball milling time is 2-5 h. Therefore, ultrafine ball-milled powder can be efficiently obtained.

In some embodiments, the volume ratio of the nano-sized silicon carbide to the bismuth telluride processing scraps is not higher than 1%.

In some embodiments, the average particle size of the nano-sized silicon carbide is not larger than 700 nm. Therefore, the hardness of the bismuth telluride-based thermoelectric nanocomposite can be improved.

In some embodiments, in step (1), the bismuth telluride processing scraps, the nano-sized silicon carbide, the antimony telluride powders and/or the tellurium powders are mixed and subjected to ball milling. Therefore, the hardness and thermoelectric performance of the bismuth telluride-based thermoelectric nanocomposite can be improved.

In some embodiments, the bismuth telluride processing scraps are compounded with the antimony telluride powders and/or the tellurium powders according to the stoichiometric ratio of Bi_{0.4}Sb_{1.6}Te₃₊ₓ where x=0.1-0.4. Therefore, the thermoelectric performance of the bismuth telluride-based thermoelectric nanocomposites can be improved.

In some embodiments, before subjecting the bismuth telluride processing scraps to the ball milling, the bismuth telluride processing scraps are pre-cleaned.

In some embodiments, in step (2), the spark plasma sintering is performed under the condition that the vacuum degree is not higher than 10 Pa.

In some embodiments, in step (2), the heating rate of the spark plasma sintering is 50-100° C./min, the sintering temperature is 400-550° C., the pressure is 40-60 MPa, and the holding time is 5-30 min Therefore, the thermoelectric performance of the bismuth telluride-based thermoelectric nanocomposites can be improved.

In another aspect of the present disclosure, a bismuth telluride-based thermoelectric nanocomposite with dispersed nano-sized silicon carbide based on the recycling of bismuth telluride processing scraps is provided. According to an embodiment of the present disclosure, the bismuth telluride-based thermoelectric nanocomposite with dispersed nano-sized silicon carbide based on the recycling of bismuth telluride processing scraps is prepared by the above method. Therefore, the bismuth telluride-based thermoelectric nanocomposite with dispersed nano-sized silicon carbide is prepared using bismuth telluride processing scraps, which significantly improves the utilization rate of bismuth telluride processing scraps, and avoids the waste of precious materials; at the same time, the obtained bismuth telluride-based thermoelectric nanocomposite with dispersed nano-sized silicon carbide has high thermoelectric performance.

The additional aspects and advantages of the present disclosure will be partly given in the following description, and partly will become obvious from the following description, or be understood through the practice of the present disclosure.

### BRIEF DESCRIPTION OF THE DRAWINGS

The above and/or additional aspects and advantages of the present disclosure will become obvious and easy to understand from the description of the embodiments in conjunction with the following drawings, wherein:

FIG. 1 is a schematic flow chart of the method for preparing a bismuth telluride-based thermoelectric nanocomposite with dispersed nano-sized silicon carbide based on the recycling of bismuth telluride processing scraps according to an embodiment of the present disclosure;

FIG. 2 is an X-ray diffraction pattern of the bismuth telluride-based thermoelectric nanocomposites with dispersed nano-sized silicon carbide obtained in Examples 1-4 and the commercially available bismuth telluride-based thermoelectric material;

FIG. 3 is a fracture scanning electron micrograph image of the bismuth telluride-based thermoelectric nanocomposite with dispersed nano-sized silicon carbide obtained in Example 1;

FIG. 4 is an EDS mapping on the polished surface of the bismuth telluride-based thermoelectric nanocomposite with dispersed nano-sized silicon carbide obtained in Example 1;

FIG. 5 shows the temperature-dependent electrical conductivity of the bismuth telluride-based thermoelectric nanocomposites with dispersed nano-sized silicon carbide obtained in Examples 1-4 and the commercially available bismuth telluride-based thermoelectric material.

FIG. 6 shows the temperature-dependent Seebeck coefficient of the bismuth telluride-based thermoelectric nanocomposites with dispersed nano-sized silicon carbide obtained in Examples 1-4 and the commercially available bismuth telluride-based thermoelectric material;

FIG. 7 shows the temperature-dependent thermal conductivity of the bismuth telluride-based thermoelectric nanocomposites with dispersed nano-sized silicon carbide obtained in Examples 1-4 and the commercially available bismuth telluride-based thermoelectric material.

FIG. 8 shows the temperature-dependent ZT value of the bismuth telluride-based thermoelectric nanocomposites with dispersed nano-sized silicon carbide obtained in Examples 1-4 and the commercially available bismuth telluride-based thermoelectric material.

FIG. 9 is a comparison diagram of the maximum ZT value and the average ZT value of the bismuth telluride-based thermoelectric nanocomposites with dispersed nano-sized silicon carbide obtained in Examples 1-4 and the commercially available bismuth telluride-based thermoelectric material.

### DETAILED DESCRIPTION OF THE EMBODIMENTS

The following detailed description of the embodiments of the present disclosure is intended to explain the present disclosure, but should not be construed as a limitation to the present disclosure.

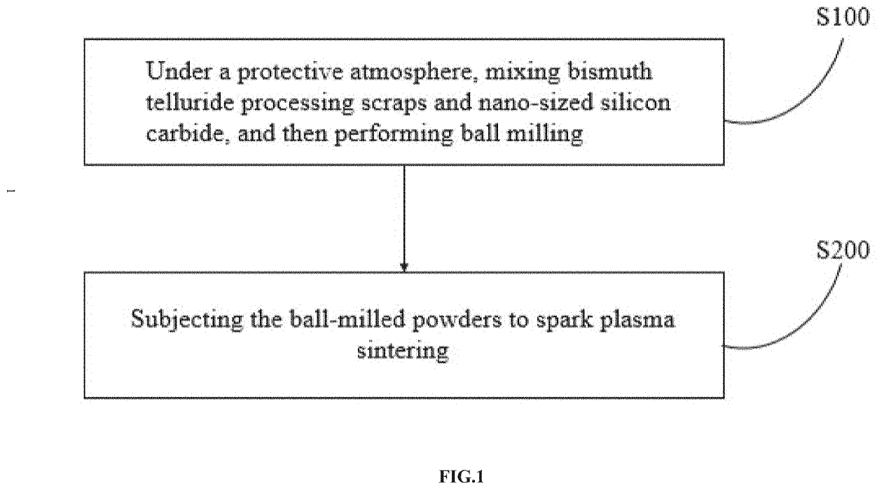

In one aspect of the present disclosure, a method for preparing a bismuth telluride-based thermoelectric nanocomposite with dispersed nano-sized silicon carbide based on the recycling of bismuth telluride processing scraps is provided. According to an embodiment of the present disclosure, referring to FIG. 1, the method includes:

S100: Under a Protective Atmosphere, Mixing the Bismuth Telluride Processing Scraps and Nano-Sized Silicon Carbide, and Performing Ball Milling

In this step, the bismuth telluride processing scraps are produced in the preparation of thermoelectric devices, for example, can be produced by Huabei Cooling Device Co., Ltd. during the preparation of thermoelectric devices. The bismuth telluride processing scraps and the nano-sized silicon carbide are mixed in a protective atmosphere and subjected to ball milling, which effectively prevents the oxidation of the corresponding elements of the bismuth telluride processing scraps. The ball milling process does not involve high temperature, which avoids the elements volatilization. Besides, ultra-fine ball-milled powders can be obtained efficiently. The incorporation of nano-sized silicon carbide can improve the thermoelectric properties of bismuth telluride, and can also enhance the hardness of the bismuth telluride material, which is conducive to material processing. It should be noted that there is no special restriction on the selection of the protective atmosphere, as long as the above functions can be achieved, for example, high-purity argon can be used. According to a specific embodiment of the present disclosure, the average particle size of the nano-sized silicon carbide used above is not larger than 700 nm, and the nano-sized silicon carbide is added according to the volume ratio of the nano-sized silicon carbide to the bismuth telluride processing scraps of not higher than 1%. The inventor found that the introduce of nano-sized silicon carbide into bismuth telluride can improve the thermoelectric performance, and can also enhance the hardness, which is beneficial to material processing. When the volume ratio of nano-sized silicon carbide to bismuth telluride processing scraps is higher than 1%, the thermal conductivity of the bismuth telluride-based thermoelectric nanocomposites with dispersed nano-sized silicon carbide will increase significantly, resulting in a decreased ZT value.

In some embodiments, before ball milling the bismuth telluride processing scraps, the bismuth telluride processing scraps should be pre-cleaned to remove oil stains and dust contaminated by cutting. For example, ultrasonic cleaning can be used to clean bismuth telluride processing scraps. Specifically, the ultrasonic cleaning can be performed in ethanol for 2-3 times, each time for 15-30 min.

Further, in this step, the bismuth telluride processing scraps, the nano-sized silicon carbide, the antimony telluride powders and/or the tellurium powders are mixed and subjected to ball milling, wherein the antimony telluride powders and the tellurium powders are both high-purity powders, and the bismuth telluride processing scraps are compounded with the antimony telluride powders and/or the tellurium powders according to the stoichiometric ratio of Bi_{0.4}Sb_{1.6}Te₃₊ₓ, where x=0.1-0.4. The addition of antimony telluride powders and/or tellurium powders for composition adjustment can further improve the thermoelectric performance of bismuth telluride.

Further, the conditions of the ball milling in this step are as follows: the weight ratio of balls to powders is (15-30):1, the ball milling speed is 400-500 r/min, and the ball milling time is 2-5 h. The inventor found that when the weight ratio of balls to powders is lower than this range, the grinding effect is poor and it is difficult to obtain fine powders. However, too high weight ratio of balls to powders will introduce too many defects, which is not conducive to improving the thermoelectric performance; at the same time, if the ball milling speed is low, the energy is not enough to completely alloy and obtain the best chemical composition. If the ball milling speed is too high, it will cause the grinding balls to stick to the inner wall of the ball mill jar, greatly reducing the efficiency of the ball milling. Correspondingly, if the ball milling time is too short, it is not conducive to the complete reaction, but the too long time will strengthen the donor-like effect and more electron carriers will be generated, which is detrimental to the thermoelectric performance. Therefore, the use of the above ball milling conditions of the present application can ensure that a bismuth telluride-based thermoelectric nanocomposite with dispersed nano-sized silicon carbide with excellent thermoelectric performance can be obtained.

S200: Subjecting the Ball-Milled Powders to Spark Plasma Sintering

In this step, the ball-milled powders obtained above are placed into a graphite mold and compacted, and then the graphite mold is placed into a sintering equipment for sintering under vacuum condition. The sintering promotes element migration, grain growth, filled pores between powders, and improved density; In addition, it is conducive to forming the bonding at the crystal grain interface, which can improve the strength, and enable the powders to be rapidly formed. After cooling, the bismuth telluride-based thermoelectric nanocomposite with dispersed nano-sized silicon carbide is obtained. Specifically, the compaction of the powders is mainly achieved by graphite molds. The sintering equipment is preferably a spark plasma sintering apparatus, e.g. spark plasma sintering is performed in the sintering equipment, and the heating rate of the spark plasma sintering is 50-100° C./min, the sintering temperature is 400-550° C., the sintering pressure is 40-60 MPa, the holding time is 5-30 min, and the vacuum degree is not higher than 10 Pa. The inventor found that if the heating rate is too slow, the material preparation efficiency will be reduced, and the crystal grain size will not be easy to control, but if the heating rate is too fast, the mold cannot follow the temperature in time, resulting in insufficient holding time and insufficient sintering, which is not conducive to the thermoelectric performance. At the same time, if the sintering temperature is too low and the time is too short, it will cause under calcined sintering and performance degradation. If the sintering temperature is too high and the time is too long, the material composition will be inhomogeneous due to the serious volatilization of the composition elements, which will affect the performance; In addition, if the sintering pressure is too low, the porosity will be high and could not obtain dense bulk. If the sintering pressure is too high, it will easily damage the mold and contaminate the sintering equipment; a certain degree of vacuum must be maintained during sintering, otherwise it will cause the oxidation of materials and deteriorate the thermoelectric performance. Therefore, the use of the above sintering conditions of the present application can improve the thermoelectric performance of the bismuth telluride-based thermoelectric nanocomposite with dispersed nano-sized silicon carbide while increasing its production efficiency.

The preparation method of the bismuth telluride-based thermoelectric nanocomposite with dispersed nano-sized silicon carbide based on the recycling of bismuth telluride processing scraps of the present disclosure has the following beneficial technical effects:

In the present disclosure, the bismuth telluride-based thermoelectric nanocomposite with dispersed nano-sized silicon carbide is prepared by the method of ball milling combined with spark plasma sintering, which has three obvious advantages compared with the prior method: First, the present disclosure recycles bismuth telluride processing scraps, which can effectively avoid the waste of precious materials; Second, the adopted recycling method has short process flow, simple operation, energy saving and high efficiency; Third, the bismuth telluride-based thermoelectric nanocomposite with dispersed nano-sized silicon carbide prepared by the present disclosure has better thermoelectric properties than the current bismuth telluride material, which is beneficial to the device service.

In another aspect of the present disclosure, a bismuth telluride-based thermoelectric nanocomposite with dispersed nano-sized silicon carbide based on the recycling of bismuth telluride processing scraps is provided. According to an embodiment of the present disclosure, the bismuth telluride-based thermoelectric nanocomposite with dispersed nano-sized silicon carbide based on the recycling of bismuth telluride processing scraps is prepared by the above method. Therefore, the bismuth telluride-based thermoelectric nanocomposite with dispersed nano-sized silicon carbide is prepared using bismuth telluride processing scraps, which significantly improves the utilization rate of bismuth telluride processing scraps, and avoids the waste of precious materials. Meanwhile, the obtained bismuth telluride-based thermoelectric nanocomposites with dispersed nano-sized silicon carbide have higher thermoelectric performance. It should be noted that the features and advantages described above for the preparation method of the bismuth telluride-based thermoelectric nanocomposites with dispersed nano-sized silicon carbide based on the recycling of bismuth telluride processing scraps are also applicable to the bismuth telluride-based thermoelectric nanocomposites with dispersed nano-sized silicon carbide based on the recycling of bismuth telluride processing scraps, which will not be repeated here.

The embodiments of the present disclosure are described in detail below. It should be noted that the embodiments described below are exemplary, and are only used to explain the present disclosure, which should not be understood as a limitation to the present disclosure. In addition, if not explicitly stated, all reagents used in the following examples are commercially available or can be synthesized according to this article or known methods. The reaction conditions not listed are also easily obtained by those skilled in this field.

### Example 1

The bismuth telluride processing scraps were ultrasonically cleaned in ethanol for two times, 15 min each time. The ultrasonically cleaned bismuth telluride processing scraps were grinded in an agate mortar and passed through a 200 mesh screen to obtain the bismuth telluride processing scraps powders. The resulting powders and nano-sized silicon carbide (the average particle size of nano-sized silicon carbide is not higher than 700 nm) were used as the initial materials, a total of 15 g powders were weighed according to the volume ratio of nano-sized silicon carbide and bismuth telluride processing scraps powders of 0.4%: 1, then the mixture was put into a stainless steel jar (volume of 250 mL) in a glove box (high-purity argon atmosphere), stainless steel balls with diameters of 10 mm and 6 mm (the total mass of the grinding balls is about 300 g) were added thereto, and the mixture was ball milled in a planetary ball mill (QM-3SP2, Nanjing University Instrument Factory) at 450 r/min for 3 h. After ball milling, the powders were taken out in the glove box (high-purity argon atmosphere) and loaded into a graphite mold;

The graphite mold loaded with ball-milled powders was compacted and then placed in a spark plasma sintering equipment (SPS), the pressure was controlled to 50 MPa, the temperature was increased to 400° C. at a heating rate of 80° C./min in a vacuum circumstance (the vacuum degree is not higher than 10 Pa), kept for 5 min, and the bulk bismuth telluride-based thermoelectric nanocomposite with dispersed nano-sized silicon carbide was obtained after cooling.

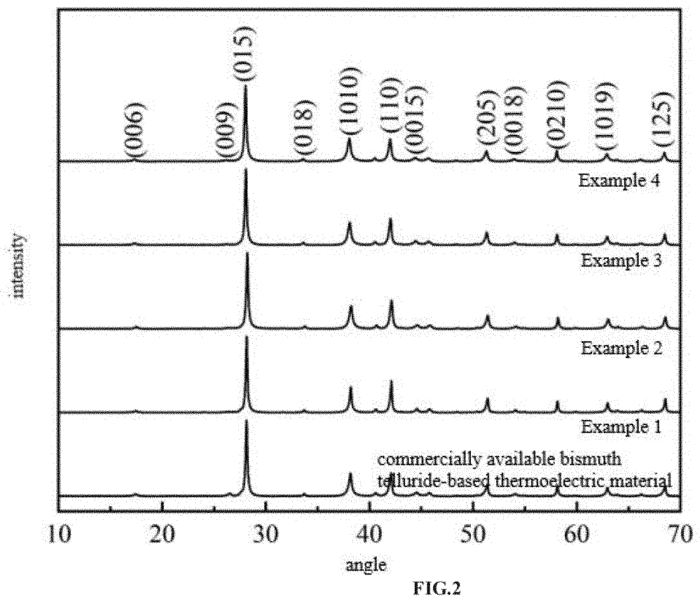

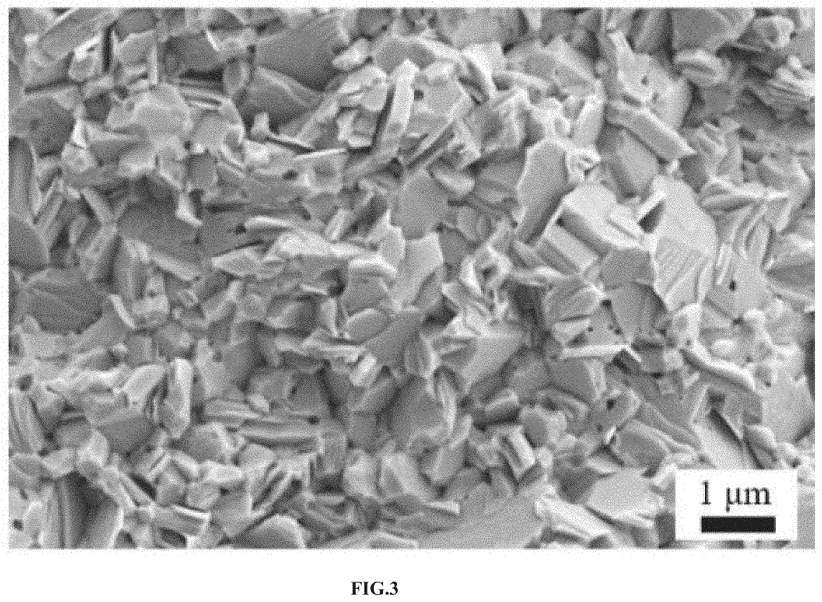

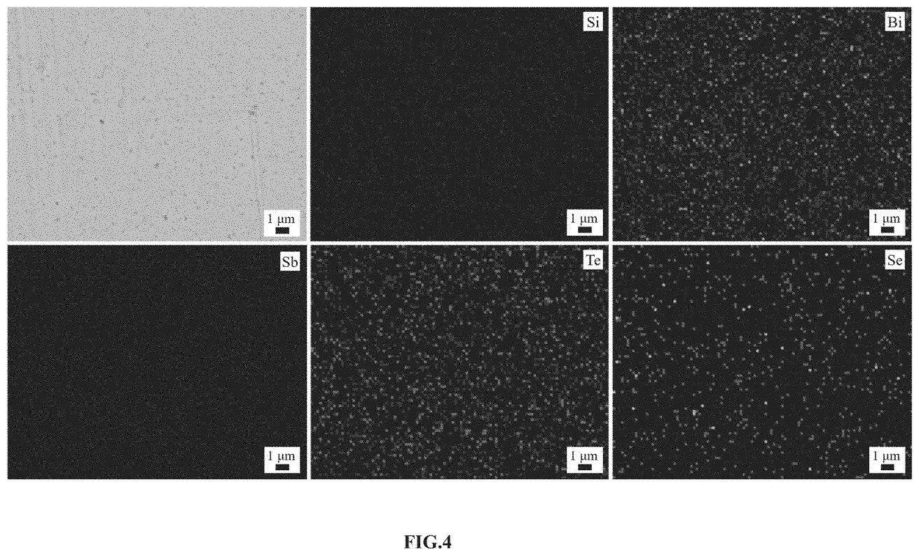

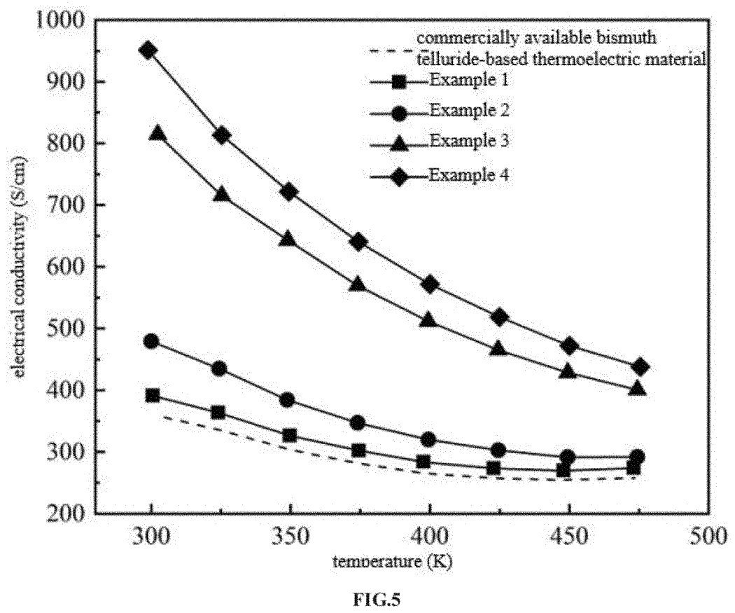

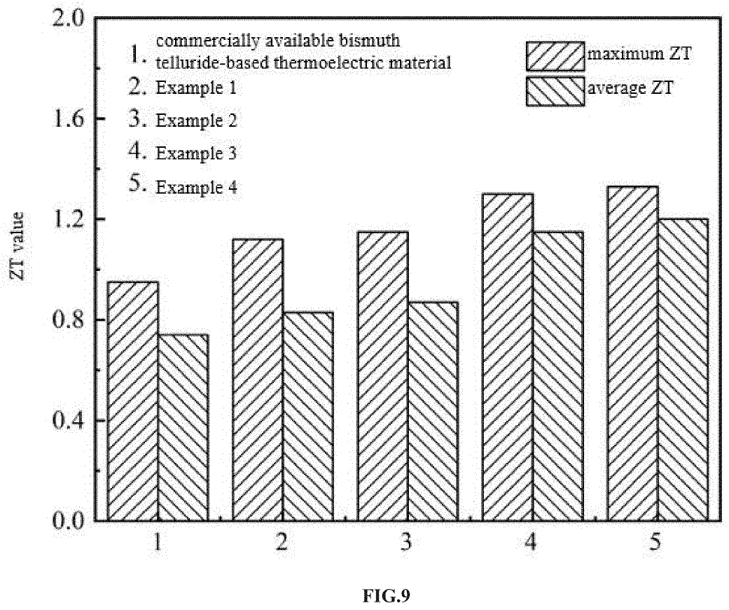

The surface of the bulk bismuth telluride-based thermoelectric nanocomposite with dispersed nano-sized silicon carbide obtained above was polished with sandpaper, and then it was analyzed by X-ray diffraction as shown in FIG. 2; FIG. 3 is a scanning electron microscope (SEM) photograph of the cross-section of the bulk bismuth telluride-based thermoelectric nanocomposite with dispersed nano-sized silicon carbide sample, and FIG. 4 is an EDS mapping of the polished surface of the bulk bismuth telluride-based thermoelectric nanocomposite with dispersed nano-sized silicon carbide; The temperature-dependent electrical conductivity, Seebeck coefficient, thermal conductivity, ZT value of the bulk bismuth telluride-based thermoelectric nanocomposites with dispersed nano-sized silicon carbide are shown in FIGS. 5, 6, 7, 8 and 9, respectively.

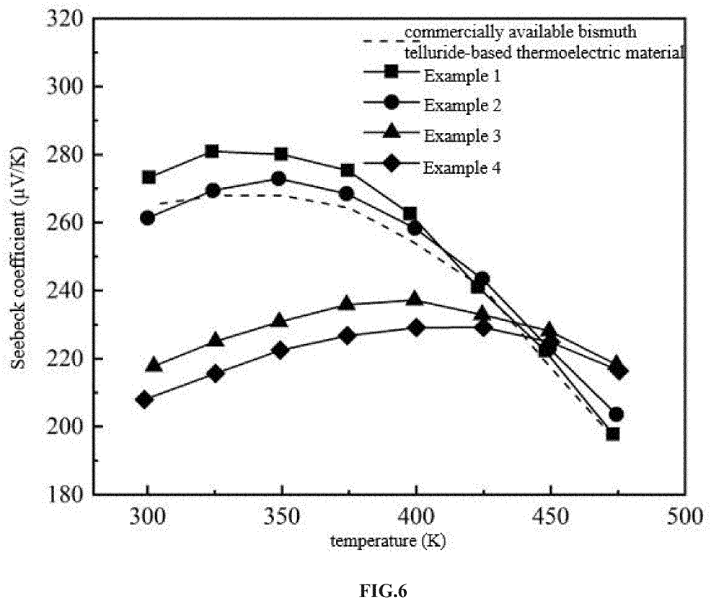

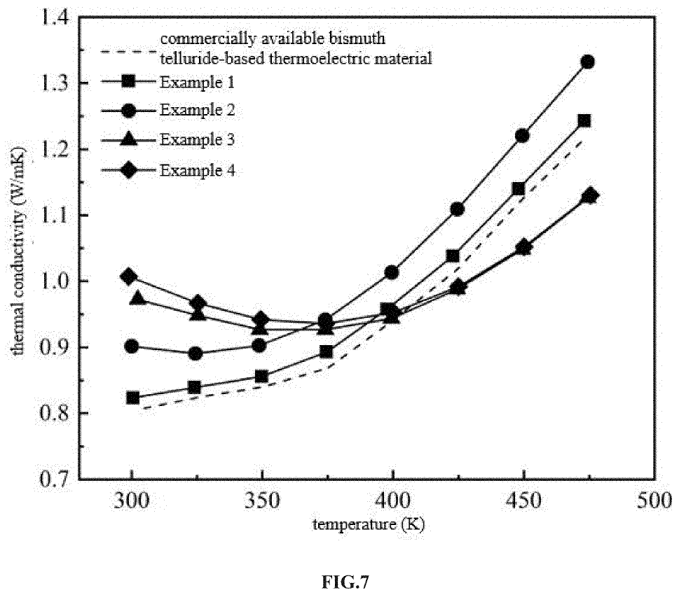

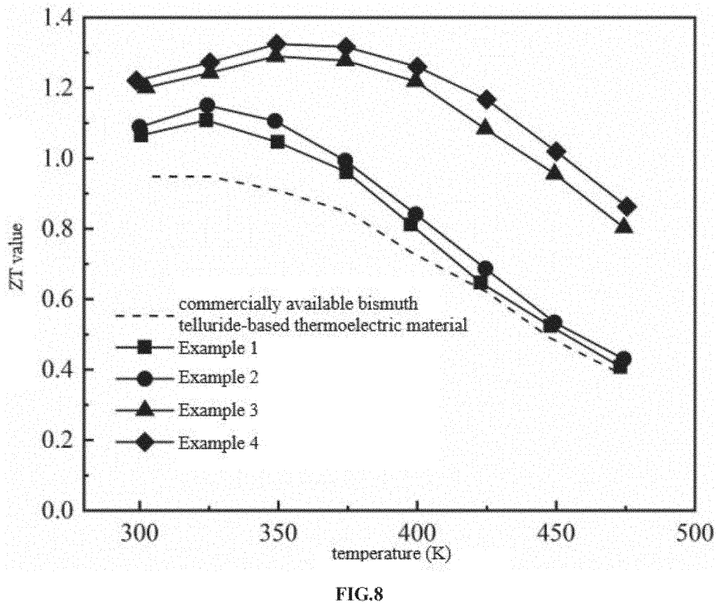

It can be seen from FIG. 2 that recycling bismuth telluride processing scraps by ball milling combined with spark plasma sintering, and making nanocomposites by dispersing nano-sized silicon carbide can obtain a pure phase bulk material. It can be seen from FIG. 4 that all elements distribute relatively homogeneously in the sample. In FIG. 5, the electrical conductivity first decreases and then increases with temperature. In FIG. 6, the Seebeck coefficient increases first and then decreases with temperature. In FIG. 7, the thermal conductivity increases with increasing temperature. It can be seen from FIG. 8 that the ZT value increases first and then decreases with the temperature, reaching 1.12 at 325 K.

### Example 2

The bismuth telluride processing scraps were ultrasonically cleaned in ethanol for three times, 20 min each time. The ultrasonically cleaned bismuth telluride processing scraps were grinded in an agate mortar and passed through a 200 mesh screen to obtain the bismuth telluride processing scraps powders. The resulting powders, nano-sized silicon carbide nanoparticles (the average particle size of nano-sized silicon carbide is not higher than 700 nm), and the tellurium powders were used as the initial materials, a total of 15 g of the powders were weighed according to the volume ratio of nano-sized silicon carbide and bismuth telluride processing scraps powders of 0.4%: 1, the tellurium powders (0.3 g) with a mass ratio of 2% were added thereto, then the mixture was put into a stainless steel jar (volume of 250 mL) in a glove box (high-purity argon atmosphere), stainless steel balls with diameters of 10 mm and 6 mm (the total mass of the grinding balls is about 300 g) were added thereto, and the mixture was ball-milled in a planetary ball mill (QM-3SP2, Nanjing University Instrument Factory) at 450 r/min for 3 h. After ball milling, the powders were taken out in the glove box (high-purity argon atmosphere) and loaded into a graphite mold;

The graphite mold loaded with ball-milled powders was compacted and then placed in a spark plasma sintering equipment (SPS), the pressure was controlled to 50 MPa, the temperature was increased to 470° C. at a heating rate of 60° C./min in a vacuum circumstance (the vacuum degree is not higher than 10 Pa), kept for 15 min, and the bulk bismuth telluride-based thermoelectric nanocomposite with dispersed nano-sized silicon carbide was obtained after cooling.

The surface of the bulk bismuth telluride-based thermoelectric nanocomposite with dispersed nano-sized silicon carbide obtained above was polished with sandpaper, and then it was analyzed by X-ray diffraction as shown in FIG. 2; The temperature-dependent electrical conductivity, Seebeck coefficient, thermal conductivity, ZT value of the bulk bismuth telluride-based thermoelectric nanocomposite with dispersed nano-sized silicon carbide, the maximum ZT value and the average ZT value are shown in FIGS. 5, 6, 7, 8 and 9, respectively. The bulk bismuth telluride-based thermoelectric nanocomposite with dispersed nano-sized silicon carbide obtained by dispersing nano-sized silicon carbide and recycling scraps under this sintering condition has the maximum ZT value of 1.15 at 325 K.

### Example 3

The bismuth telluride processing scraps were ultrasonically cleaned in ethanol for two times, 25 min each time. The ultrasonically cleaned bismuth telluride processing scraps were grinded in an agate mortar and passed through a 200 mesh screen to obtain the bismuth telluride processing scraps powders. The resulting powders, nano-sized silicon carbide (the average particle size of nano-sized silicon carbide is not higher than 700 nm), antimony telluride powders and tellurium powders were used as the initial materials, a total of 15 g powders were weighed according to the volume ratio of nano-sized silicon carbide and bismuth telluride processing scraps of 0.4%: 1 and the bismuth telluride processing scraps powders, antimony telluride powders and tellurium powders were weighed according to the stoichiometric ratio of Bi_{0.4}Sb_{1.6}Te_{3.2}, then the mixture was put into a stainless steel jar (volume of 250 mL) in a glove box (high-purity argon atmosphere), stainless steel balls with diameters of 10 mm and 6 mm (the total mass of the grinding balls is about 300 g) were added thereto, the mixture was ball-milled in a planetary ball mill (QM-3SP2, Nanjing University Instrument Factory) at 450 r/min for 3 h, and then the powders were taken out in the glove box;

The ball-milled powders were loaded into a graphite mold, compacted and then placed in a spark plasma sintering equipment (SPS), the pressure was controlled to 50 MPa, the temperature was increased to 520° C. at a heating rate of 50° C./min in a vacuum circumstance (the vacuum degree is not higher than 10 Pa), kept for 15 min, and the bulk bismuth telluride-based thermoelectric nanocomposite with dispersed nano-sized silicon carbide was obtained after cooling.

Similarly, the surface of the bulk bismuth telluride-based thermoelectric nanocomposite with dispersed nano-sized silicon carbide obtained above was polished with sandpaper and the corresponding measurements were performed. It can be seen from FIG. 2 that the bulk bismuth telluride-based thermoelectric nanocomposite with dispersed nano-sized silicon carbide is a pure phase block. The temperature-dependent electrical conductivity, Seebeck coefficient, thermal conductivity, ZT value of the sample, the maximum ZT value and the average ZT value are shown in FIGS. 5, 6, 7, 8 and 9, respectively. The bulk bismuth telluride-based thermoelectric nanocomposite with dispersed nano-sized silicon carbide obtained by the composition adjustment and dispersing nano-sized silicon carbide under this sintering condition has the maximum ZT value of 1.29 at 350 K.

### Example 4

The bismuth telluride processing scraps were ultrasonically cleaned in ethanol for two times, 18 min each time. The ultrasonically cleaned bismuth telluride processing scraps were grinded in an agate mortar and passed through a 200 mesh screen to obtain the bismuth telluride processing scraps powders. The resulting powders, nano-sized silicon carbide (the average particle size of nano-sized silicon carbide is not higher than 700 nm), antimony telluride powders and tellurium powders were used as the initial materials, a total of 15 g powders were weighed according to the volume ratio of nano-sized silicon carbide and bismuth telluride processing scraps powders of 0.4%: 1, the bismuth telluride processing scraps powders, antimony telluride powders and tellurium powders were weighed according to the stoichiometric ratio of Bi_{0.4}Sb_{1.6}Te_{3.2}, then the mixture was put into a stainless steel jar (volume of 250 mL) in a glove box (high-purity argon atmosphere), stainless steel balls with diameters of 10 mm and 6 mm (the total mass of the grinding balls is about 300 g) were added thereto, the mixture was ball-milled in a planetary ball mill (QM-3SP2, Nanjing University Instrument Factory) at 450 r/min for 3 h, and then the powders were taken out in the glove box;

The ball-milled powders were loaded into a graphite mold, compacted and then placed in a spark plasma sintering equipment (SPS), the pressure was controlled to 50 MPa, the temperature was increased to 520° C. at a heating rate of 50° C./min in a vacuum circumstance (the vacuum degree is not higher than 10 Pa), kept for 30 min, and the bulk bismuth telluride-based thermoelectric nanocomposite with dispersed nano-sized silicon carbide was obtained after cooling.

Similarly, the surface of the bulk bismuth telluride-based thermoelectric nanocomposite with dispersed nano-sized silicon carbide obtained above was polished with sandpaper and the corresponding measurements were performed. It can be seen from FIG. 2 that the bulk bismuth telluride-based thermoelectric nanocomposite with dispersed nano-sized silicon carbide is a pure phase block. The temperature-dependent electrical conductivity, Seebeck coefficient, thermal conductivity, ZT value of the sample, the maximum ZT value and the average ZT value are shown in FIGS. 5, 6, 7, 8 and 9, respectively. The bulk bismuth telluride-based thermoelectric nanocomposite with dispersed nano-sized silicon carbide obtained by composition adjustment and dispersing nano-sized silicon carbide under this sintering condition has the maximum ZT value of 1.33 at 350 K. Note: The commercially available bismuth telluride-based thermoelectric material is produced by Huabei Cooling Device Co., Ltd.

In the description of this specification, descriptions with reference to the terms “one embodiment”, “some embodiments”, “examples”, “specific examples”, or “some examples” etc. mean specific features described in conjunction with the embodiment or example. In this specification, the schematic representations of the above terms do not necessarily refer to the same embodiment or example. Moreover, the described specific features, structures, materials or characteristics can be combined in any one or more embodiments or examples in a suitable manner. In addition, the persons skilled in the art can combine the different embodiments or examples and the features of the different embodiments or examples described in this specification without contradicting each other.

Although the embodiments of the present disclosure have been shown and described above, it can be understood that the above embodiments are exemplary and should not be construed as limiting the present disclosure. The persons skilled in the art can make changes, modifications, and substitutions to the above embodiments within the scope of the present disclosure.

1. A method for preparing a bismuth telluride-based thermoelectric nanocomposite with dispersed nano-sized silicon carbide based on the recycling of bismuth telluride processing scraps, wherein comprising:
(1) Under a protective atmosphere, mixing bismuth telluride processing scraps and nano-sized silicon carbide, and then performing ball milling;
(2) Subjecting the ball-milled powders to spark plasma sintering to obtain a bismuth telluride-based thermoelectric nanocomposite with dispersed nano-sized silicon carbide.

2. The method according to claim 1, wherein, in step (1), the conditions of the ball milling are as follows: the weight ratio of balls to powders is (15-30):1, the ball milling speed is 400-500 r/min, and the ball milling time is 2-5 h.

3. The method according to claim 1, wherein, the volume ratio of the nano-sized silicon carbide to the bismuth telluride processing scraps is not higher than 1%.

4. The method according to claim 1, wherein, the average particle size of the nano-sized silicon carbide is not larger than 700 nm.

5. The method according to claim 1, wherein, in step (1), the bismuth telluride processing scraps, the nano-sized silicon carbide, the antimony telluride powders and/or the tellurium powders are mixed and subjected to ball milling.

6. The method according to claim 5, wherein, the bismuth telluride processing scraps are compounded with the antimony telluride powders and/or the tellurium powders according to the stoichiometric ratio of Bi_{0.4}Sb_{1.6}Te₃₊ₓ, where x=0.1-0.4.

7. The method according to claim 1, wherein, before subjecting the bismuth telluride processing scraps to the ball milling, the bismuth telluride processing scrap is pre-cleaned.

8. The method according to claim 1, wherein, in step (2), the spark plasma sintering is performed under the vacuum condition that the vacuum degree is not higher than 10 Pa.

9. The method according to claim 1, wherein, in step (2), the heating rate of the spark plasma sintering is 50-100° C./min, the sintering temperature is 400-550° C., the pressure is 40-60 MPa, and the holding time is 5-30 min.

10. A bismuth telluride-based thermoelectric nanocomposite with dispersed nano-sized silicon carbide based on the recycling of bismuth telluride processing scraps, wherein the bismuth telluride-based thermoelectric nanocomposite with dispersed nano-sized silicon carbide based on the recycling of bismuth telluride processing scraps is prepared by the method of claim 1.

11. The bismuth telluride-based thermoelectric nanocomposite with dispersed nano-sized silicon carbide according to claim 10, wherein, in step (1), the conditions of the ball milling are as follows: the weight ratio of balls to powders is (15-30):1, the ball milling speed is 400-500 r/min, and the ball milling time is 2-5 h.

12. The bismuth telluride-based thermoelectric nanocomposite with dispersed nano-sized silicon carbide according to claim 10, wherein, the volume ratio of the nano-sized silicon carbide to the bismuth telluride processing scraps is not higher than 1%.

13. The bismuth telluride-based thermoelectric nanocomposite with dispersed nano-sized silicon carbide according to claim 10, wherein, the average particle size of the nano-sized silicon carbide is not larger than 700 nm.

14. The bismuth telluride-based thermoelectric nanocomposite with dispersed nano-sized silicon carbide according to claim 10, wherein, in step (1), the bismuth telluride processing scraps, the nano-sized silicon carbide, the antimony telluride powders and/or the tellurium powders are mixed and subjected to ball milling.

15. The bismuth telluride-based thermoelectric nanocomposite with dispersed nano-sized silicon carbide according to claim 14, wherein, the bismuth telluride processing scraps are compounded with the antimony telluride powders and/or the tellurium powders according to the stoichiometric ratio of Bi_{0.4}Sb_{1.6}Te₃₊ₓ, where x=0.1-0.4.

16. The bismuth telluride-based thermoelectric nanocomposite with dispersed nano-sized silicon carbide according to claim 10, wherein, before subjecting the bismuth telluride processing scraps to the ball milling, the bismuth telluride processing scraps are pre-cleaned.

17. The bismuth telluride-based thermoelectric nanocomposite with dispersed nano-sized silicon carbide according to claim 10, wherein, in step (2), the spark plasma sintering is performed under the vacuum condition that the vacuum degree is not higher than 10 Pa.

18. The bismuth telluride-based thermoelectric nanocomposite with dispersed nano-sized silicon carbide according to claim 10, wherein, in step (2), the heating rate of the spark plasma sintering is 50-100° C./min, the sintering temperature is 400-550° C., the pressure is 40-60 MPa, and the holding time is 5-30 min.
